(19) United States
(12) Patent Application Publication
(10) Pub. No.: US 2025/0374429 A1
(43) Pub. Date: Dec. 4, 2025

(54) ELECTRONIC DEVICE

(71) Applicant: Advanced Semiconductor Engineering, Inc., Kaohsiung (TW)

(72) Inventors: Ming-Hao HSIEH, Kaohsiung (TW); Chien-Wei CHANG, Kaohsiung (TW); Wen Hung HUANG, Kaohsiung (TW); Min Lung HUANG, Kaohsiung (TW)

(73) Assignee: Advanced Semiconductor Engineering, Inc., Kaohsiung (TW)

(21) Appl. No.: 18/731,214

(22) Filed: May 31, 2024

(51) Int. Cl. H05K 1/11; H05K 1/16; H05K 3/42

(52) U.S. Cl. CPC H05K 1/116; H05K 1/114; H05K 1/162; H05K 3/429; H05K 2201/10515

(57) ABSTRACT

An electronic device is provided. The electronic device includes an electronic component and a first group of conductive vias. The electronic component has a first group of terminals disposed on a lower surface of the electronic component and a second group of terminals disposed on an upper surface of the electronic component. The first group of terminals includes a first terminal and a second terminal disposed at different elevations. The first group of conductive vias is electrically connected to the first group of terminals.

### BACKGROUND

### 1. Field of the Disclosure

The present disclosure relates to an electronic device, and particularly to an electronic device integrating an electronic component configured to receive power by a backside surface.

### 2. Description of the Related Art

The power delivery efficiency of an electronic component can be significantly affected by the disconnection between the electronic component and the terminals of a circuit structure, which in turn can impact the reliability of the electronic device. In order to enhance the performance of the electronic device, it is essential to develop new technologies or improve existing ones.

### SUMMARY

In some embodiments, an electronic device includes an electronic component and a first group of conductive vias. The electronic component has a first group of terminals disposed on a lower surface of the electronic component and a second group of terminals disposed on an upper surface of the electronic component. The first group of terminals includes a first terminal and a second terminal disposed at different elevations. The first group of conductive vias is electrically connected to the first group of terminals.

In some embodiments, an electronic device includes an electronic component and a first group of conductive vias. The electronic component has a lower surface and an upper surface. The first group of conductive vias is disposed under the lower surface of the electronic component and electrically connected to the electronic component. The first group of conductive vias has different lengths.

In some embodiments, an electronic device includes a lower circuit structure, an electronic component, and first interconnections. The lower circuit structure has a substantially flat surface. The electronic component is disposed over the substantially flat surface of the lower circuit structure. The electronic component has a lower curved surface facing the substantially flat surface. The first interconnections are disposed between the substantially flat surface of the lower circuit structure and the lower curved surface of the electronic component.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1A illustrates a cross-sectional view of an example of an electronic device according to some embodiments of the present disclosure.

FIG. 1B illustrates a partial enlarged view of the electronic component of FIG. 1A according to some embodiments of the present disclosure.

FIG. 1C illustrates a partial enlarged view of the electronic device of FIG. 1A according to some embodiments of the present disclosure.

FIG. 2 illustrates a cross-sectional view of an example of an electronic device according to some embodiments of the present disclosure.

FIG. 3 illustrates a cross-sectional view of an example of an electronic device according to some embodiments of the present disclosure.

FIG. 4 illustrates a perspective view of an example of an electronic device according to some embodiments of the present disclosure.

FIG. 5 illustrates a cross-sectional view of an example of an electronic device according to some embodiments of the present disclosure.

FIG. 6 illustrates a cross-sectional view of an example of an electronic device according to some embodiments of the present disclosure.

FIG. 7A, FIG. 7B, FIG. 7C, FIG. 7D, FIG. 7E, FIG. 7F, FIG. 7G, FIG. 7H, FIG. 7I, FIG. 7J, FIG. 7K, and FIG. 7L illustrate various stages of an example of a method for manufacturing an electronic device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides for many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

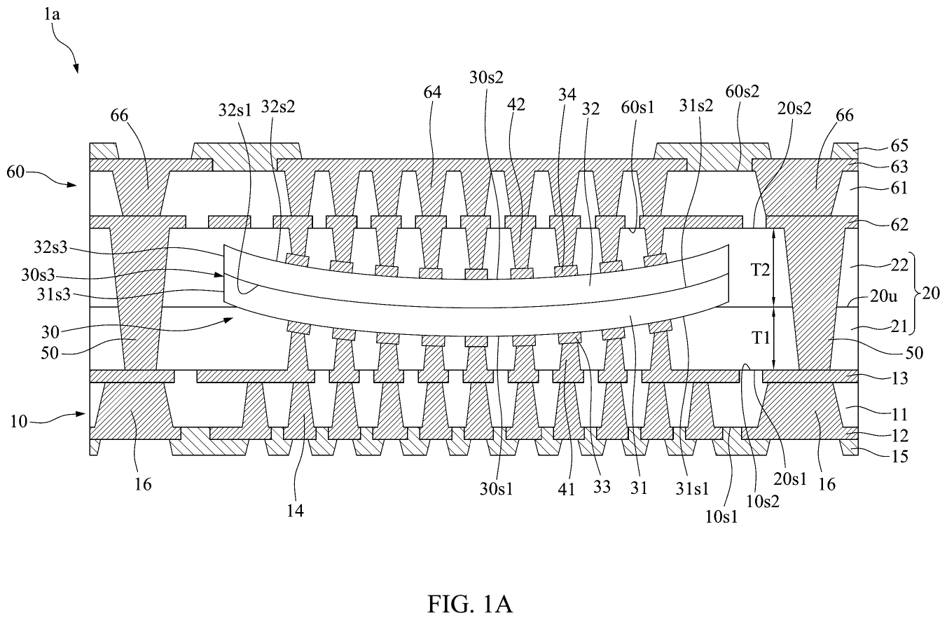

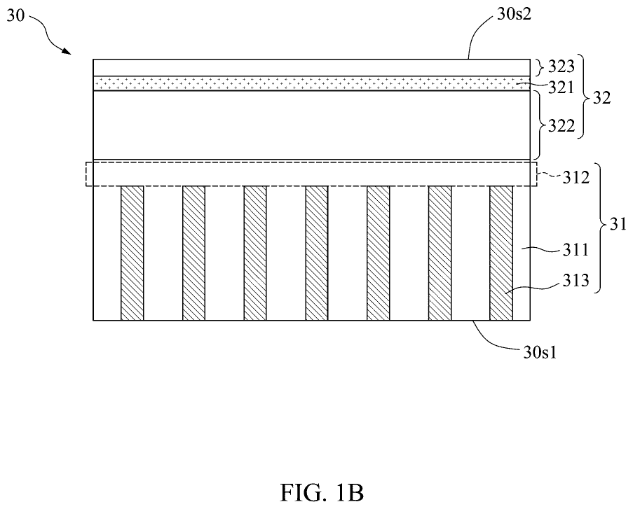

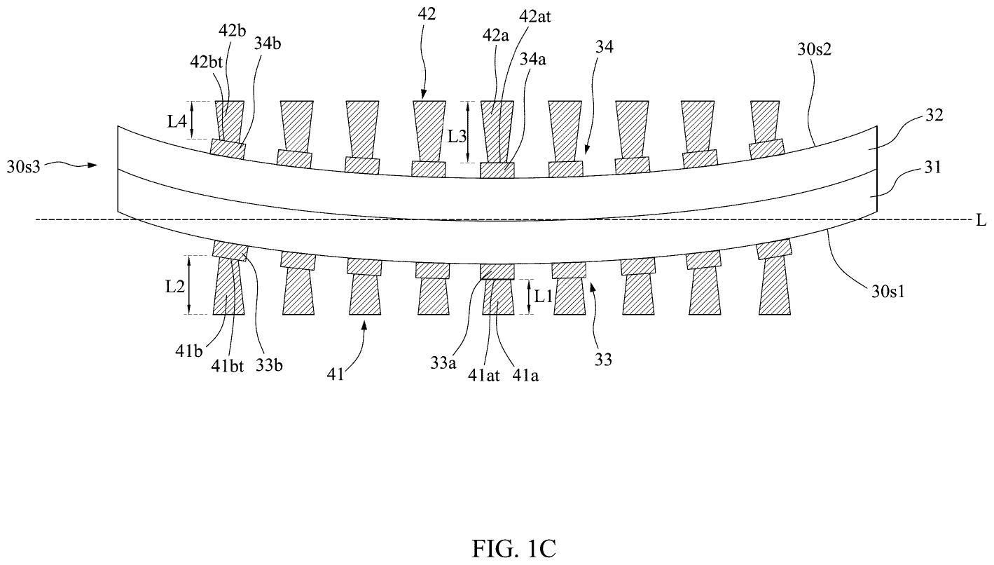

FIG. 1A illustrates a cross-sectional view of an electronic device 1a according to some embodiments of the present disclosure. In some embodiments, the electronic device 1a may include a circuit structure 10, a dielectric structure 20, an electronic component 30, interconnections 41, interconnections 42, interconnections 50, and a circuit structure 60.

The circuit structure 10 (or a lower circuit structure) may include a substrate 11, a conductive layer 12, a conductive layer 13, interconnections 14, and a dielectric layer 15, and interconnections 16. The circuit structure 10 may have a surface 10s1 (or a lower surface) and a surface 10s2 (or an upper surface) opposite to the surface 10s1. In some embodiments, the surface 10s2 may be a substantially flat surface.

The substrate 11 may be a core substrate. The core substrate may include prepreg (PP), Ajinomoto build-up film (ABF) or other suitable materials. In some embodiments, a resin material used in the core substrate may be a fiber-reinforced resin so as to strengthen the core substrate, and the reinforcing fibers may be, but are not limited to, glass fibers or Kevlar fibers (aramid fibers). The lower surface of the substrate 11 may be defined as the surface 10s1. The upper surface of the substrate 11 may be defined as the surface 10s2.

The conductive layer 12 may be disposed under, within, and/or adjacent to the surface 10s1 of the circuit structure 10. The conductive layer 12 may be electrically connected to an external device (not shown), such as a printed circuit board (PCB), a power regulating component (e.g., a power management integrated circuit), or other suitable components. The conductive layer 13 may be disposed over, within, and/or adjacent to the surface 10s2 of the circuit structure 10. The interconnection 14 may be disposed within the substrate 11. The interconnection 14 may electrically connect the conductive layer 12 to the conductive layer 13. The interconnection 14 may include a conductive via, which is tapered toward the surface 10s2 of the circuit structure 10. The interconnection 16 may be electrically connected to the interconnection 50. The interconnection 16 may include a conductive via, which is tapered toward the surface 10s2 of the circuit structure 10. Each of the conductive layer 12, conductive layer 13, and interconnections 14 and 16 may include a seed layer and a conductive material on the seed layer. The seed layer may include metal, metal oxide, metal nitride, metal carbide, metal alloy, or suitable materials. For example, the seed layer may include tantalum nitride, tantalum, titanium nitride, titanium, cobalt tungsten, tungsten nitride, or the like. The conductive material may include copper, aluminum, tungsten, chromium, gold, silver, other suitable materials, or a combination thereof.

The dielectric layer 15 may be disposed under the surface 10s1 of the circuit structure 10. The dielectric layer 15 may be patterned to expose a portion of the conductive layer 12. The dielectric layer 15 may include a solder resist, such as a polymer material including bismaleimide triazine, polypropylene or an epoxy-based material.

In some embodiments, the dielectric structure 20 (or carrier) may be disposed on or over the surface 10s2 of the circuit structure 10. The dielectric structure 20 may be configured to encapsulate the electronic component 30, interconnections 41, interconnections 42, and interconnections 50. The dielectric structure 20 may have a surface 20s1 (or a lower surface) abutting the circuit structure 10 and a surface 20s2 (or an upper surface) opposite to the surface 20s1. In some embodiments, the dielectric structure 20 may include an encapsulant 21 and an encapsulant 22.

In some embodiments, the encapsulant 21 (or bottom encapsulant) may be disposed on the surface 10s2 of the circuit structure 10. In some embodiments, the encapsulant 21 may be in contact with the substrate 11. The encapsulant 21 may include an insulation or dielectric material. In some embodiments, the encapsulant 21 may be made of molding material that may include, for example, a novolac-based resin, an epoxy-based resin, a silicone-based resin, or other suitable materials. In some embodiments, the encapsulant 21 may include, for example, organic materials (e.g., a molding compound, a bismaleimide triazine, polyimide, polybenzoxazole, a polypropylene, or an epoxy-based material), inorganic materials (e.g., a silicon, a glass, a ceramic or a quartz), liquid and/or dry-film materials or a combination thereof. The lower surface of the encapsulant 21 may be defined as the surface 20s1 of the dielectric structure 20.

In some embodiments, the encapsulant 22 (or top encapsulant) may be disposed on or over the encapsulant 21. The encapsulant 22 may be in contact with the encapsulant 21. The encapsulants 21 and 22 may have an interface 20u therebetween. In some embodiments, the material of the encapsulant 22 may be the same as or similar to that of the encapsulant 21. In some embodiments, the thickness T2 of the encapsulant 22 may be greater than the thickness T1 of the encapsulant 21. The upper surface of the encapsulant 22 may be defined as the surface 20s2 of the dielectric structure 20.

In some embodiments, the electronic component 30 may be disposed on or over the surface 10s2 of the circuit structure 10. In some embodiments, a portion of the electronic component 30 may be disposed within the encapsulant 21. In some embodiments, a portion of the electronic component 30 may be disposed within the encapsulant 22. The electronic component 30 may have a surface 30s1 (or a lower surface), a surface 30s2 (or an upper surface) opposite to the surface 30s1, and a surface 30s3 (or a lateral surface or a side) extending between the surface 30s1 and surface 30s2. In some embodiments, the electronic component 30 may have a surface area (e.g., the surface area of the surface 30s2) equal to or less than 200 mm², such as 150 mm², 100 mm², 50 mm², 10 mm², or less. In some embodiments, the electronic component 30 may have a thickness equal to or less than 50 μm, such as 50 μm, 40 um, 30 μm, 20 um, 15 μm, 10 um, or less. In some embodiments, the electronic component 30 may have terminals 33 disposed under the surface 30s1 and terminals 34 disposed over the surface 30s2. Due to the relatively small surface area, thickness, and the presence of terminals 33 and 34 on two opposite sides, the profile of electronic component 30 may become bent or distorted as a result of warpage.

In some embodiments, the surface 30s1 of the electronic component 30 may be a curved surface due to warpage. In some embodiments, the surface 30s1 of the electronic component 30 may protrude toward the circuit structure 10. For example, the central region of the surface 30s1 has an elevation lower than that of the peripheral region, which is closer to the surface 30s3, of the surface 30s1 with respect to the surface 10s2 of the circuit structure 10. In some embodiments, the surface 30s2 of the electronic component 30 may be a curved surface due to warpage. In some embodiments, the surface 30s2 of the electronic component 30 may be concaved. For example, the central region of the surface 30s2 has an elevation lower than that of the peripheral region of the surface 30s2 with respect to the surface 10s2 of the circuit structure 10 (or with respect to the circuit structure 60).

Please refer to FIG. 1B, which illustrates an enlarged view of the electronic component 30. In some embodiments, the electronic component 30 may include a passive component 31 and an active component 32 over the passive component 31. It should be noted that the electronic component 30 shown in FIG. 1B has a substantially flat surface 30s1 and surface 30s2 for brevity, and the present disclosure is not intended to be limiting.

In some embodiments, the passive component 31 (or a carrier) may be configured to consume, store, and transmit energy. In some embodiments, the passive component 31 may be configured to stabilize, adjust, receive, and/or transmit power. In some embodiments, the passive component 31 may include a capacitor, inductor, resistor, filter, or a combination of such components. The capacitor may include a deep trench capacitor (DTC), a multi-layer ceramic capacitor (MILCC) or other capacitors. The passive component 31 may include a substrate 311, a passive element region 312, and conductive structures 313.

The substrate 311 may include a semiconductor substrate. The substrate 311 may include silicon or germanium in a single crystal form, a polycrystalline form, or an amorphous form. The lower surface of the substrate 311 may function as the surface 30s1 of the electronic component 30, which may also be defined as the backside surface of the electronic component 30.

The passive element region 312 may be embedded in the substrate 311. The passive element region 312 may abut the active component 32. In some embodiments, the passive element region 312 may define one or more capacitors and include a metal-insulator-metal (MIM) structure or other suitable structures.

The conductive structure 313 may extend between the surface 30s1 and the passive element region 312. The conductive structure 313 may penetrate a portion of the substrate 311. The conductive structure 313 may be electrically connected to the passive element region 312. In some embodiments, the conductive structure 313 may include a through silicon via (TSV). The conductive structure 313 may be configured to receive and/or transmit power. The conductive structure 313 may include copper, aluminum, gold, silver, tungsten, nickel, a combination thereof or other suitable materials.

In some embodiments, the active component 32 may be disposed on or over the passive component 31. The active component 32 may be configured to receive power. The active component 32 may be configured to generate and/or process a signal. The active component 32 may include a semiconductor die or a chip, such as a logic die (e.g., application processor (AP), system-on-a-chip (SoC), central processing unit (CPU), graphics processing unit (GPU), microcontroller, etc.), a memory die (e.g., dynamic random access memory (DRAM) die, static random access memory (SRAM) die, etc.), a radio frequency (RF) die, a sensor die, a micro-electro-mechanical-system (MEMS) die, a signal processing die (e.g., digital signal processing (DSP) die), a front-end die (e.g., analog front-end (AFE) dies) or other active components. The upper surface (e.g., surface 32s2) of the active component 32 may function as the surface 30s2 of the electronic component 30, which may also be defined as an active surface. As used herein, the term “active surface” may refer to a surface through which a signal (e.g., I/O signal) passes. In some embodiments, the active component 32 may have an integrated circuit (IC) layer 321, a redistribution structure 322, and a redistribution structure 323.

The IC layer 321 may include one or more ICs formed within the base, such as a semiconductor substrate. The IC layer 321 may be configured to receive power (or a power signal), and generate a signal (or a non-power signal), such as an input/out (I/O) signal or other signals.

The redistribution structure 322 (or a power delivery network (PDN)) may be disposed under the IC layer 321. In some embodiments, the redistribution structure 322 may be configured to receive and/or transmit power, which may include or be composed of direct current (DC), to the IC layer 321. The redistribution structure 322 may include one or more conductive traces and conductive vias embedded within one or more dielectric layers.

The redistribution structure 323 may be disposed over the IC layer 321. The redistribution structure 323 may be configured to receive and/or transmit a signal (e.g., I/O signal), which may include or be composed of alternating current (AC). In some embodiments, the redistribution structure 323 may include one or more conductive traces and conductive vias embedded within one or more dielectric layers.

Please refer back to FIG. 1A, wherein a portion of the passive component 31 may be disposed within the encapsulant 21. In some embodiments, a portion of the encapsulant 21 may be disposed within the encapsulant 22. In some embodiments, the active component 32 may be disposed within the encapsulant 22. In some embodiments, the active component 32 may be spaced apart from the encapsulant 21. In some embodiments, the passive component 31 may have a surface 31s1 (or a lower surface), a surface 31s2 (or an upper surface), and a surface 31s3 (or a lateral surface) extending between the surface 31s1 and surface 31s2. In some embodiments, a portion of the surface 31s1 may be in contact with the encapsulant 21. In some embodiments, a portion of the surface 31s1 may be in contact with the encapsulant 22. In some embodiments, the surface 31s3 may be in contact with the encapsulant 22. In some embodiments, the surface 31s3 may be spaced apart from the encapsulant 21.

In some embodiments, the active component 32 may have a surface 32s1 (or a lower surface), a surface 32s2 (or an upper surface), and a surface 32s3 (or a lateral surface) extending between the surface 32s1 and surface 32s2. In some embodiments, the surface 32s3 may be in contact with the encapsulant 22. In some embodiments, the surface 32s3 may be spaced apart from the encapsulant 22. In some embodiments, the interface between the surface 31s2 and surface 32s1 may be located within the encapsulant 22.

The interconnections 41 (or first group of interconnections) may be disposed on or over the surface 10s2 of the circuit structure 10. The interconnections 41 may be electrically connected to the circuit structure 10. In some embodiments, the interconnections 41 may be electrically connected to the electronic component 30 through the terminals 33. In some embodiments, the interconnections 41 may be embedded within the encapsulant 21. The interconnections 41 may include a seed layer (e.g., titanium nitride) and a conductive material (e.g., copper) on the seed layer. The interconnection 41 may include a conductive via which is tapered toward the electronic component 30.

The interconnections 42 (or second group of interconnections) may be disposed on or under the circuit structure 60. The interconnections 42 may be electrically connected to the circuit structure 60. In some embodiments, the interconnections 42 may be electrically connected to the electronic component 30 through the terminals 34. In some embodiments, the interconnections 42 may be embedded within the encapsulant 22. The interconnections 42 may include a seed layer (e.g., titanium nitride) and a conductive material (e.g., copper) on the seed layer. The interconnection 42 may include a conductive via which is tapered toward the electronic component 30.

The interconnections 50 may be disposed on or over the surface 10s2 of the circuit structure 10. In some embodiments, the interconnection 50 may be disposed between the circuit structure 10 and circuit structure 60. The interconnection 50 may be electrically connected to the circuit structure 10. The interconnection 50 may be electrically connected to the circuit structure 60. In some embodiments, the interconnection 50 may include a conductive pillar or a conductive via which is tapered toward the circuit structure 10. In some embodiments, the interconnection 50 may penetrate the encapsulant 21. In some embodiments, the interconnection 50 may penetrate the encapsulant 22. In some embodiments, the dimension (e.g., the diameter or width) of the interconnection 50 may be greater than that of the interconnections 41 (or interconnection 42). The interconnection 50 may include a seed layer (e.g., titanium nitride) and a conductive material (e.g., copper) on the seed layer.

In some embodiments, the circuit structure 60 may be disposed on or over the encapsulant 22. In some embodiments, the circuit structure 60 may be electrically connected to the interconnections. In some embodiments, the circuit structure 60 may be electrically connected to the electronic component 30 through the terminals 34. The circuit structure 60 may include a substrate 61, a conductive layer 62, a conductive layer 63, interconnections 64, and a dielectric layer 65. The circuit structure 60 may have a surface 60s1 (or a lower surface) and a surface 60s2 (or an upper surface) opposite to the surface 60s1. The substrate 61 may be a core substrate. The core substrate may include prepreg, ABF or other suitable materials. In some embodiments, a resin material used in the core substrate may be a fiber-reinforced resin so as to strengthen the core substrate, and the reinforcing fibers may be, but are not limited to, glass fibers or Kevlar fibers (aramid fibers). The lower surface of the substrate 61 may be defined as the surface 60s1. The upper surface of the substrate 61 may be defined as the surface 60s2.

The conductive layer 62 may be disposed under, within, and/or adjacent to the surface 60s1 of the circuit structure 60. The conductive layer 63 may be disposed over, within, and/or adjacent to the surface 60s2 of the circuit structure 60. The conductive layer 63 may be electrically connected to an external device (not shown), such as a printed circuit board or other suitable components. The interconnection 64 may be disposed within the substrate 61. The interconnection 64 may electrically connect the conductive layer 62 to the conductive layer 63. The interconnection 64 may include a conductive via, which is tapered toward the surface 60s1 of the circuit structure 60. The interconnection 66 may be electrically connected to the interconnection 50. The interconnection 66 may include a conductive via, which is tapered toward the surface 60s1 of the circuit structure 60. Each of the conductive layer 62, conductive layer 63, and interconnections 64 and 66 may include a seed layer and a conductive material on the seed layer. The seed layer may include metal, metal oxide, metal nitride, metal carbide, metal alloy, or suitable materials. For example, the seed layer may include tantalum nitride, tantalum, titanium nitride, titanium, cobalt tungsten, tungsten nitride, or the like. The conductive material may include copper, aluminum, tungsten, chromium, gold, silver, other suitable materials, or a combination thereof.

The dielectric layer 65 may be disposed over the surface 60s2 of the circuit structure 60. The dielectric layer 65 may be patterned to expose a portion of the conductive layer 63. The dielectric layer 65 may define openings exposing a portion of the conductive layer 63. The dielectric layer 65 may include a solder resist, such as a polymer material including bismaleimide triazine, polypropylene or an epoxy-based material.

Please refer to FIG. 1C, which illustrates a partial enlarged view of the electronic device 1a. In some embodiments, each of the terminals 33 (or first group of terminals) may be located at different elevations with respect to the surface 10s2 of the circuit structure 10. The terminals 33 may include a terminal 33a located at a central region of the surface 30s1 and a terminal 33b located at a peripheral region, which is closer to the surface 30s3, of the surface 30s1. In some embodiments, the terminal 33a may be at an elevation lower than that of the terminal 33b with respect to the surface 10s2 of the circuit structure 10. In some embodiments, the top of the terminal 33a, which is in contact with the passive component 31, may be at an elevation lower than that of the top of the terminal 33b with respect to the surface 10s2 of the circuit structure 10. In some embodiments, the bottom of the terminal 33a, which is in contact with the interconnection 41, may be at an elevation lower than that of the bottom of the terminal 33b with respect to the surface 10s2 of the circuit structure 10.

The interconnections 41 may include an interconnection 41a connected to the terminal 33a and an interconnection 41b connected to the terminal 33b. In some embodiments, the top 41at (e.g., top surface or top end) of the interconnection 41a, which is in contact with the terminal 33, may be at an elevation lower than that of the top 41bt (e.g., top surface or top end) of the interconnection 41b with respect to the surface 10s2 of the circuit structure 10. In some embodiments, the bottom (e.g., bottom surface or bottom end) of the interconnection 41a, which is in contact with the circuit structure 10 (shown in FIG. 1A), may be at an elevation the same as that of the bottom (e.g., bottom surface or bottom end) of the interconnection 41b with respect to the surface 10s2 of the circuit structure 10. In some embodiments, each of the interconnections 41 may have a different length, which is defined as a distance between the bottom of the terminal 33 and the surface 10s2 of the circuit structure 10. In some embodiments, the length L1 of the interconnection 41a may be less than the length L2 of the interconnection 41b. In some embodiments, the top 41at of the interconnection 41a may be a substantially planar surface or a slanted surface. In some embodiments, the top 41bt of the interconnection 41b may be a slanted surface. In some embodiments, the slope of the top 41bt, an angle defined by the top 41bt and a direction parallel to an axis L, may be greater than the slope of the top 41at, an angle defined by the top 41at and a direction parallel to the axis L.

In some embodiments, each of the terminals 34 (or second group of terminals) may be located at different elevations. The terminals 34 may include a terminal 34a located at a central region of the surface 30s2 and a terminal 34b located at a peripheral region, which is closer to the surface 30s3, of the surface 30s2. In some embodiments, the terminal 34a may be at an elevation lower than that of the terminal 34b with respect to the surface 10s2 of the circuit structure 10 (or with respect to the circuit structure 60). In some embodiments, the top of the terminal 34a, which is in contact with the interconnection 42, may be at an elevation lower than that of the top of the terminal 34b with respect to the surface 10s2 of the circuit structure 10. In some embodiments, the bottom of the terminal 34a, which is in contact with the active component 32, may be at an elevation lower than that of the bottom of the terminal 34b with respect to the surface 10s2 of the circuit structure 10.

The interconnections 42 may include an interconnection 42a connected to the terminal 34a and an interconnection 42b connected to the terminal 34b. In some embodiments, the bottom 42at (e.g., bottom surface or bottom end) of the interconnection 42a, which is in contact with the terminal 34, may be at an elevation lower than that of the bottom 42bt (e.g., bottom surface or bottom end) of the interconnection 42b with respect to the surface 10s2 of the circuit structure 10. In some embodiments, the top (e.g., top surface or top end) of the interconnection 42a, which is in contact with the circuit structure 60 (shown in FIG. 1A), may be at an elevation the same as that of the top (e.g., top surface or top end) of the interconnection 42b with respect to the surface 10s2 of the circuit structure 10. In some embodiments, each of the interconnections 42 may have a different length, which is defined as a distance between the top of the terminals 34 and the surface 60s1 of the circuit structure 60. In some embodiments, the length L3 of the interconnection 42a may be greater than the length L4 of the interconnection 42b. In some embodiments, the bottom 42at of the interconnection 42a may be a substantially planar surface or a slanted surface. In some embodiments, the bottom 42bt of the interconnection 42b may be a slanted surface. In some embodiments, the slope of the bottom 42bt, an angle defined by the bottom 42bt and a direction parallel to the axis L, may be greater than the slope of the bottom 42at, an angle defined by the bottom 42at and a direction parallel to the axis L.

In some embodiments, the sum of the length of one of the interconnections 41 and the length of a corresponding one of the interconnections 42 is substantially constant or uniform. For example, the sum of the length L1 of the interconnection 41a and the length L3 of the interconnection 42a which vertically overlaps the interconnection 41a is the same as the sum of the length L2 of the interconnection 41b and the length L4 of the interconnection 42b which vertically overlaps the interconnection 41b.

In some embodiments, an arrangement of the interconnections 41 and an arrangement of the interconnections 42 are non-symmetrical with respect to the electronic component 30. In some embodiments, an arrangement of the interconnections 41 and an arrangement of the interconnections 42 are non-symmetrical with respect to an axis L passing through the center (or gravity center) of the electronic component 30. The axis L may be substantially parallel to surface 10s2 of the circuit structure 10. For example, the distance between the interconnection 41b and the axis L is different from the distance between the interconnection 42b and the axis L. In some embodiments, an arrangement of the terminals 33 and an arrangement of the terminals 34 are non-symmetrical with respect to an axis L passing through the center (or gravity center) of the electronic component 30. For example, the distance between the terminal 34b and the axis L is different from the distance between the terminal 33b and the axis L.

In this embodiment, the electronic component 30 is embedded within the encapsulants 21 and 22, which helps alleviate the warpage issue associated with the electronic component 30. In this embodiment, the interconnections 41 and interconnections 42 are formed by a via-last technique, which can form trenches or openings with different depths based on the elevations of the terminals 33 and terminals 34. In a comparative example, disconnection may occur at the interface between the terminal and the interconnection due to the warpage of an electronic component. In contrast, in this embodiment, the terminals (e.g., terminals 33) may be connected to the interconnections (e.g., interconnections 41) with greater precision and accuracy. Thus, the reliability of the electronic device 1a can be enhanced.

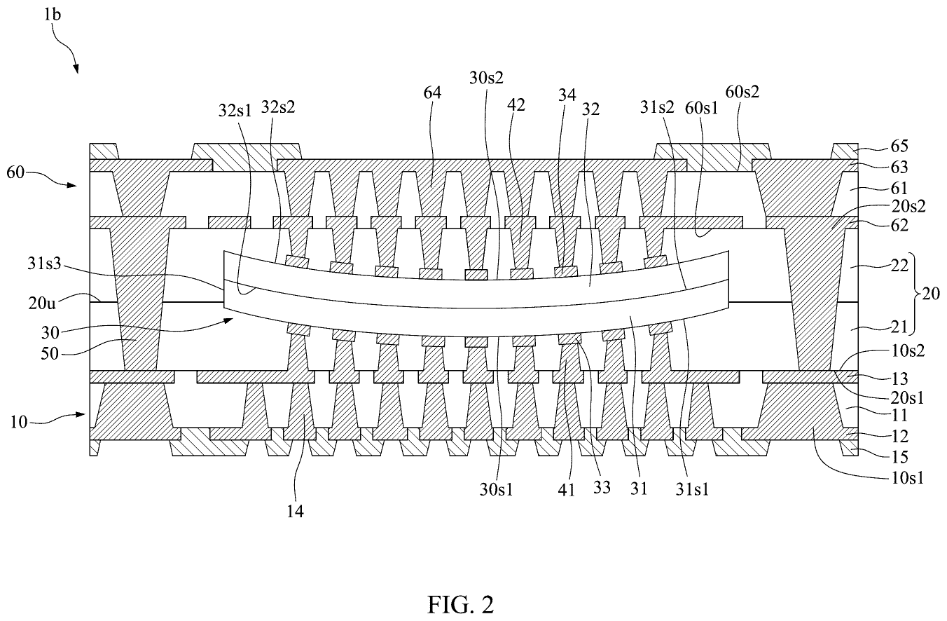

FIG. 2 illustrates a cross-sectional view of an example of an electronic device 1b according to some embodiments of the present disclosure. The electronic device 1b is similar to the electronic device 1a, and the differences therebetween are described below.

In some embodiments, a portion of the surface 31s3 may be in contact with the encapsulant 21. The surface 31s3 may be partially in contact with the encapsulant 22. In some embodiments, the edge of the surface 31s1 and surface 31s3 may be in contact with the encapsulant 21. In some embodiments, the surface 31s3 may be in contact with or intersect the interface 20u of the encapsulants 21 and 22.

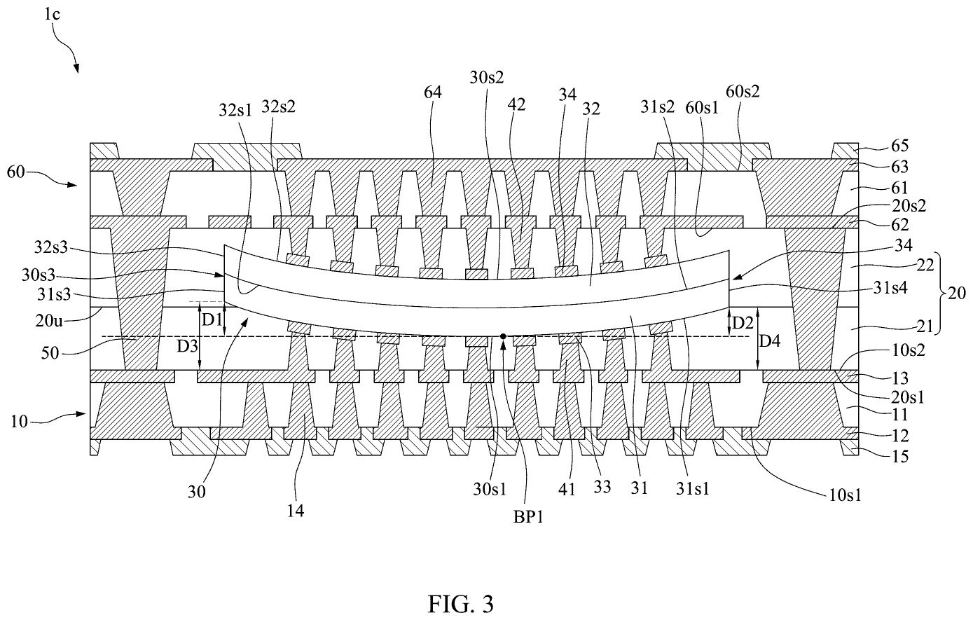

FIG. 3 illustrates a cross-sectional view of an example of an electronic device 1c according to some embodiments of the present disclosure. The electronic device 1c is similar to the electronic device 1a, and the differences therebetween are described below.

The electronic component 30 may include a surface 30s4 opposite to the surface 30s3. The passive component 31 may include a surface 31s4 opposite to the surface 31s3. In some embodiments, the elevation difference D1 between the bottommost point BP1 of the surface 31s1 and the edge between the surface 31s1 and the surface 31s3 may be different from the elevation difference D2 between the bottommost point BP1 of the surface 31s1 and the edge between the surface 31s1 and the surface 31s4. In some embodiments, the elevation difference D3 between the surface 10s2 of the circuit structure 10 and the edge between the surface 31s1 and the surface 31s3 of the passive component 31 may be different from the elevation difference D4 between the surface 10s2 of the circuit structure 10 and the edge between the surface 31s1 and the surface 31s4 of the passive component 31. In some embodiments, the elevation difference D3 between the surface 10s2 of the circuit structure 10 and the edge between the surface 30s1 and the surface 30s3 of the electronic component 30 may be different from the elevation difference D4 between the surface 10s2 of the circuit structure 10 and the edge between the surface 30s1 and the surface 30s4 of the electronic component 30. In some embodiments, a portion of the interface 20u of the encapsulants 21 and 22 may be under the surface 30s1. In some embodiments, the interface 20u of the encapsulants 21 and 22 may be in contact with or intersect the surface 30s4.

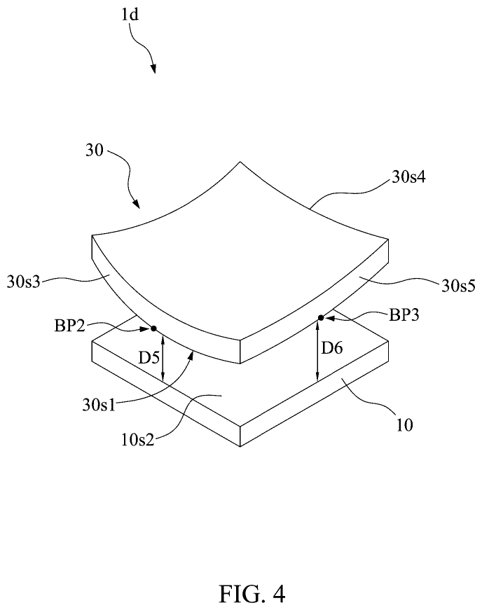

FIG. 4 illustrates a perspective view of an example of an electronic device 1d according to some embodiments of the present disclosure. The electronic device 1d is similar to the electronic device 1a, and the differences therebetween are described below.

The electronic component 30 may include a surface 30s5 extending between the surface 30s3 and surface 30s4. The surface 30s3 may be adjacent to the surface 30s5. In some embodiments, the warpage (or distortion) of the surface 30s3 may be different from that of the surface 30s5. In some embodiments, the elevation difference D5 between the surface 10s2 of the circuit structure 10 and the bottommost point BP2 of the edge between the surface 30s3 and surface 30s1 of the electronic component 30 may be different from the elevation difference D6 between the surface 10s2 of the circuit structure 10 and the bottommost point BP3 of the edge between the surface 30s5 and surface 30s1 of the electronic component 30.

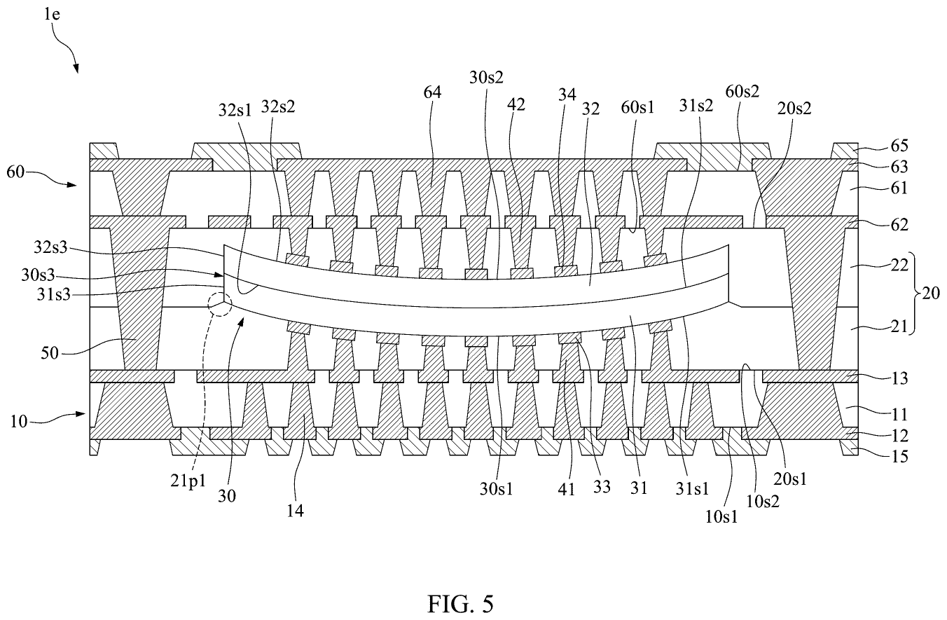

FIG. 5 illustrates a cross-sectional view of an example of an electronic device 1e according to some embodiments of the present disclosure. The electronic device 1e is similar to the electronic device 1a, and the differences therebetween are described below.

In some embodiments, the encapsulant 21 may include a protruding portion 21p1. In some embodiments, the protruding portion 21p1 may protrude from the upper surface (not annotated) of the encapsulant 21. In some embodiments, the protruding portion 21p1 may connect the electronic component 30 and the upper surface of the encapsulant 21. In some embodiments, the protruding portion 21p1 may be in contact with the surface 30s1 or the surface 31s3 of the electronic component 30. In some embodiments, the elevation of the protruding portion 21p1 may be higher than that of a portion of the lower surface of the encapsulant 22 with respect to the surface 10s2 of the circuit structure 10.

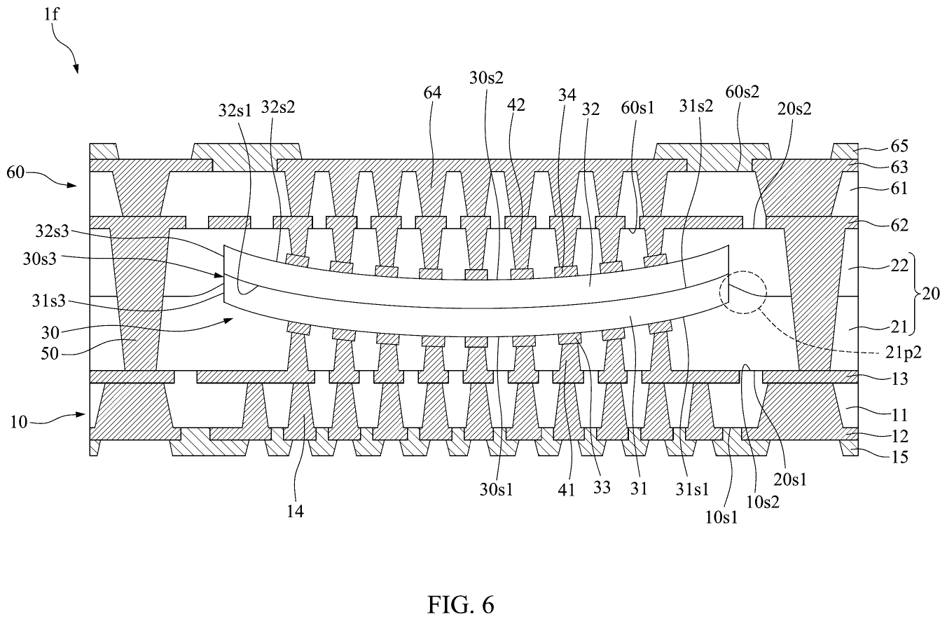

FIG. 6 illustrates a cross-sectional view of an example of an electronic device if according to some embodiments of the present disclosure. The electronic device if is similar to the electronic device 1e, and the differences therebetween are described below.

In some embodiments, the encapsulant 21 may include a protruding portion 21p2. In some embodiments, the protruding portion 21p2 may protrude from the upper surface of the encapsulant 21. The protruding portion 21p2 may have a curved profile. In some embodiments, the protruding portion 21p2 may connect the surface 30s3 of the electronic component 30 and the upper surface of the encapsulant 21. In some embodiments, the protruding portion 21p2 may be in contact with the surface 30s3 of the electronic component 30. In some embodiments, the protruding portion 21p2 may be in contact with the surface 31s3 of the passive component 31. In some embodiments, the elevation of the protruding portion 21p2 may be higher than that of a portion of the lower surface of the encapsulant 22 with respect to the surface 10s2 of the circuit structure 10.

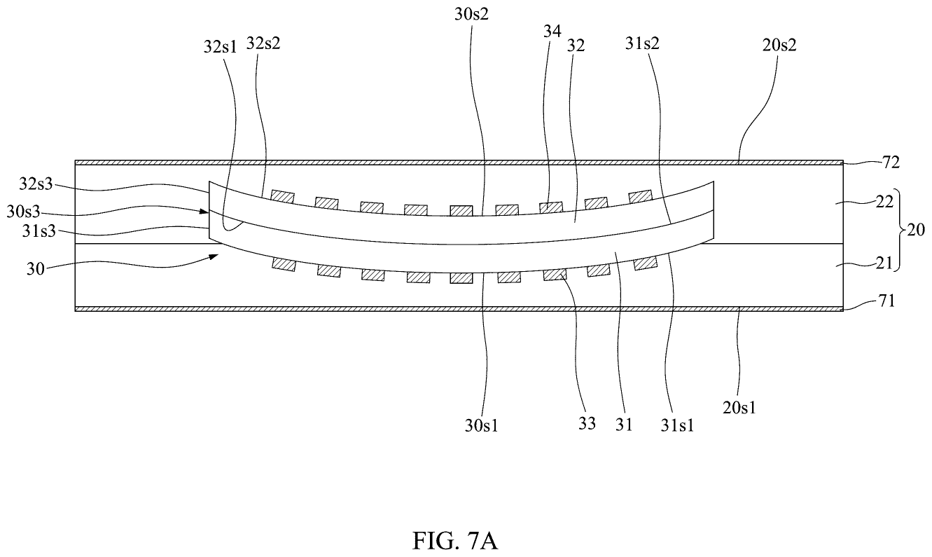

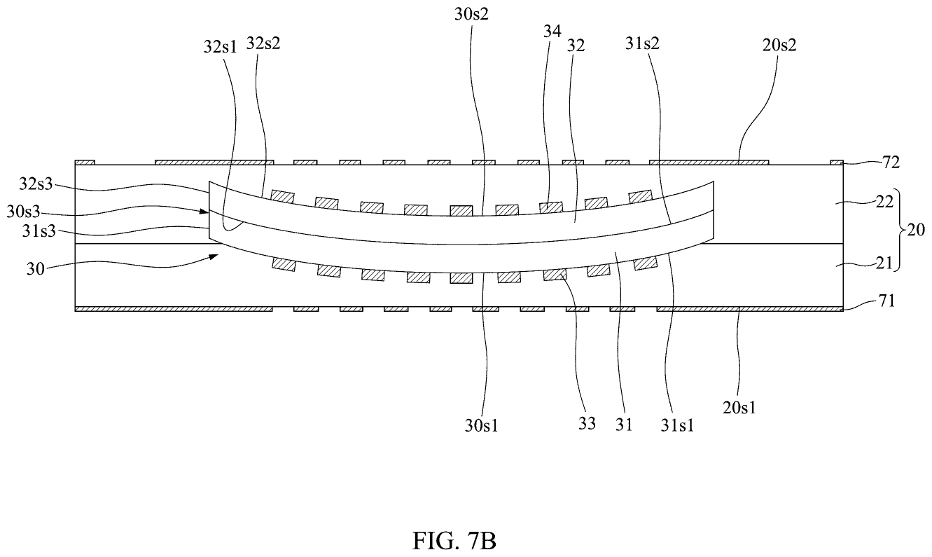

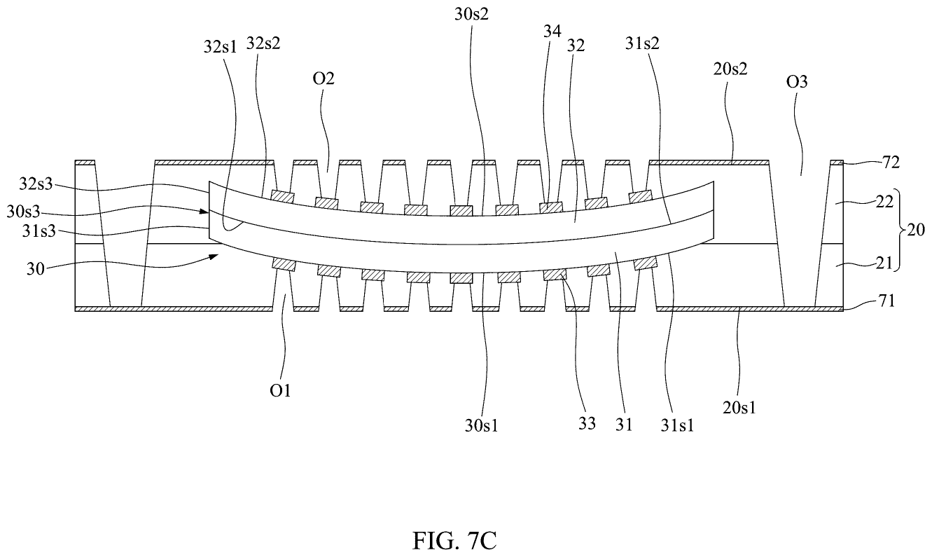

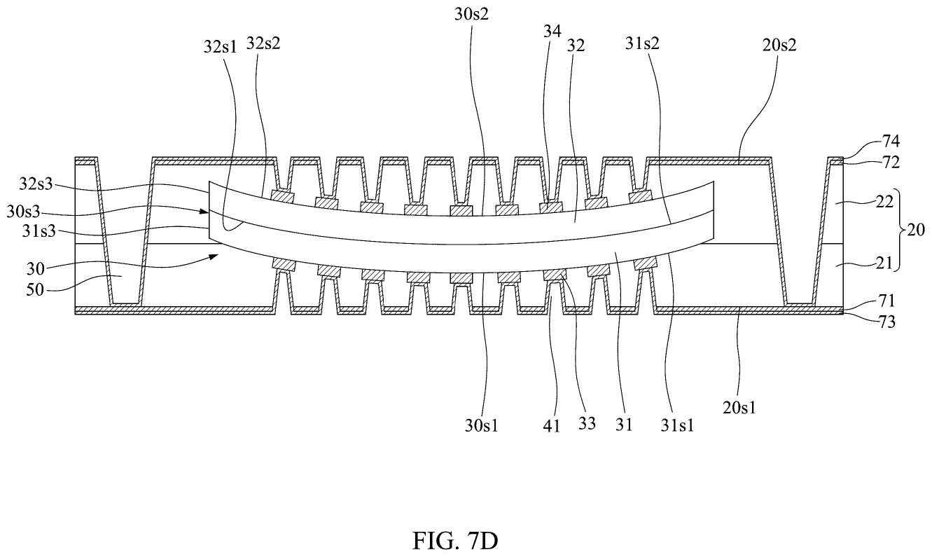

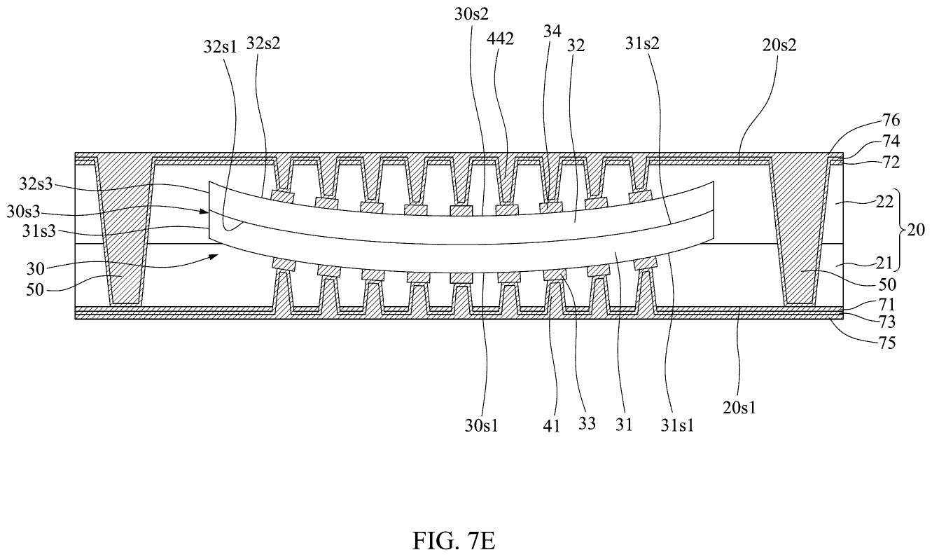

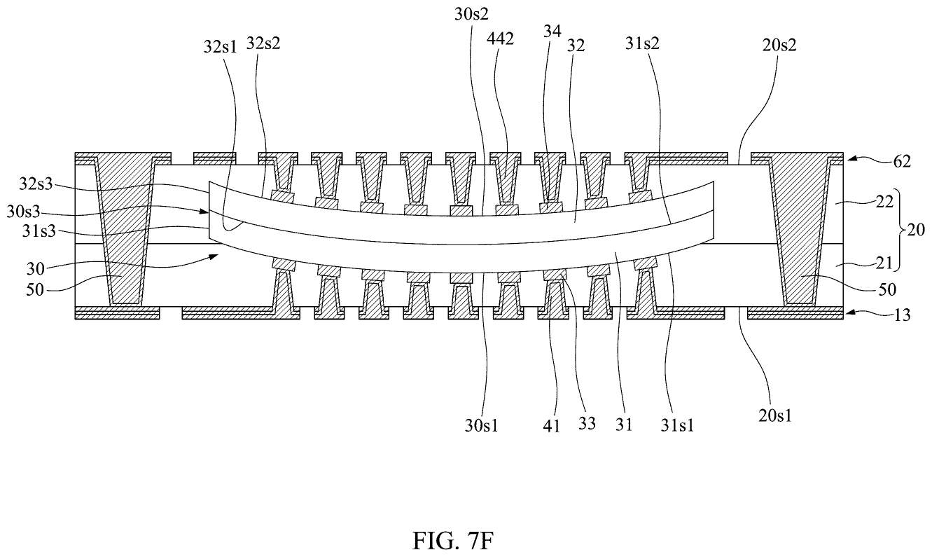

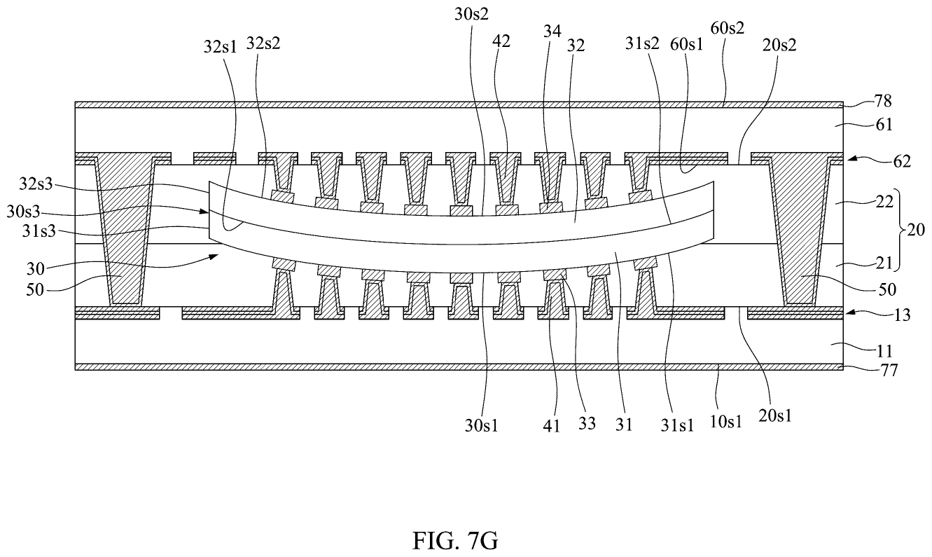

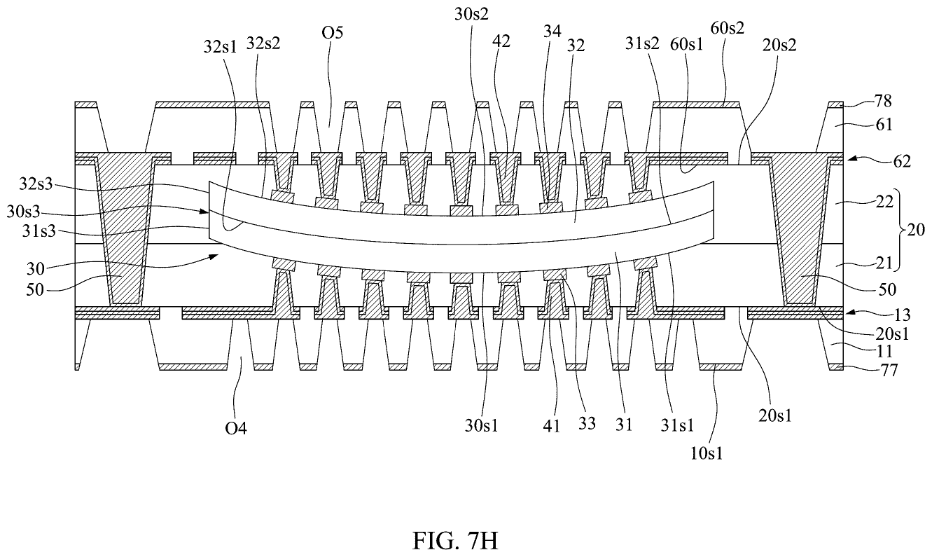

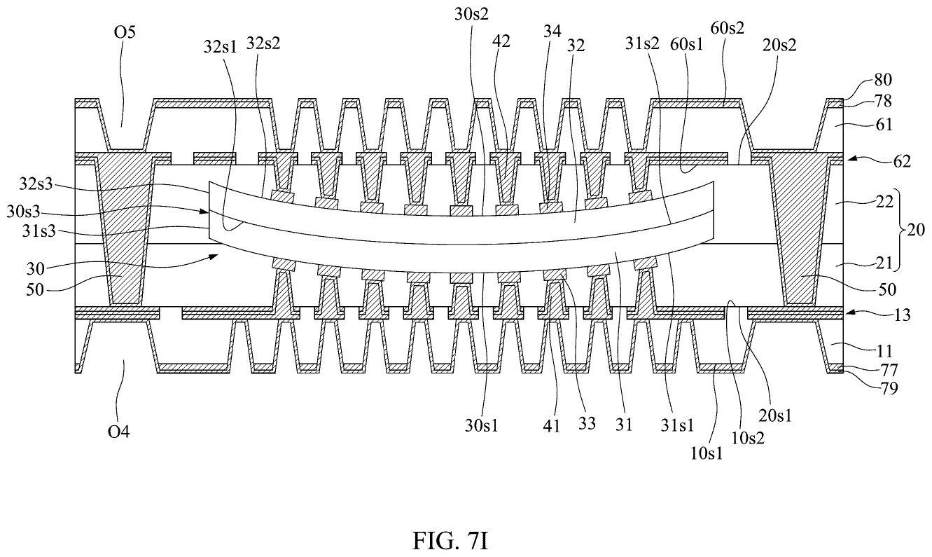

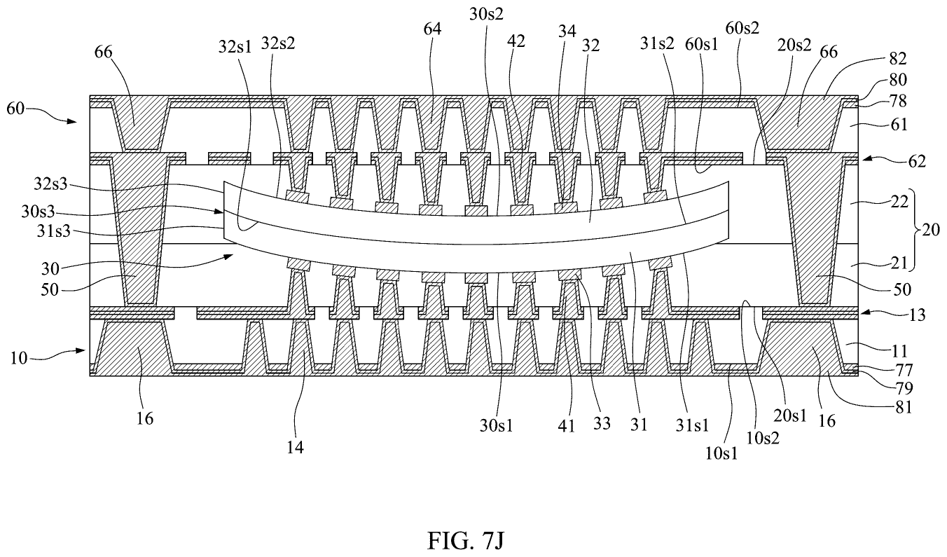

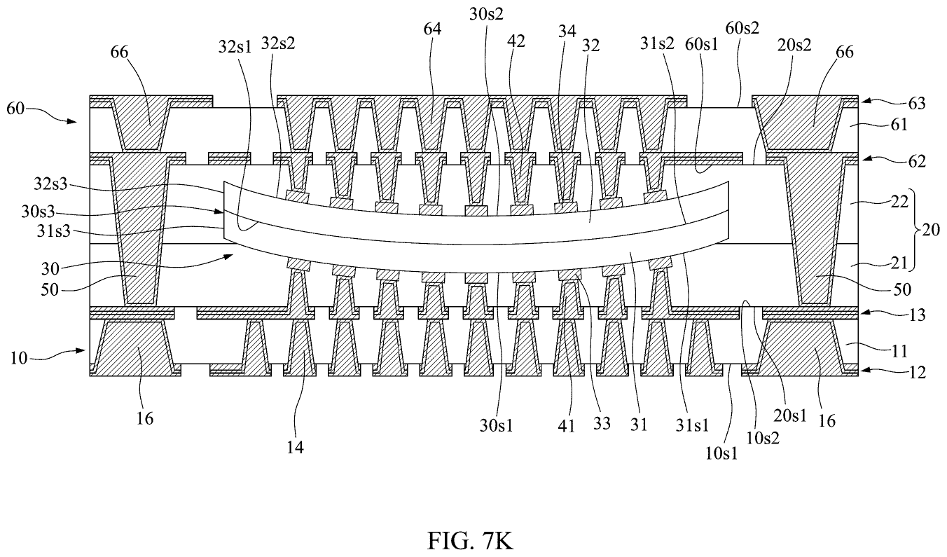

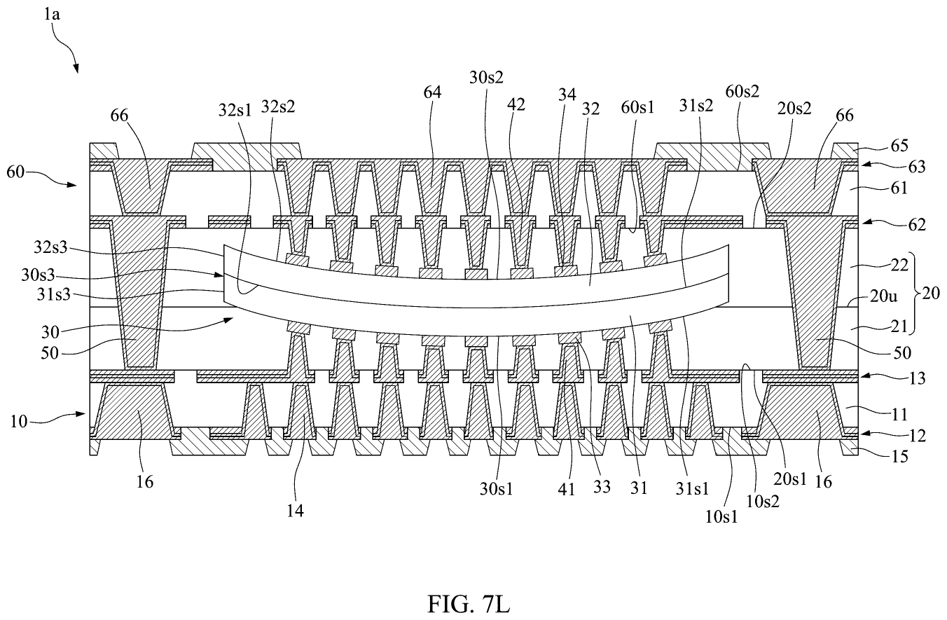

FIGS. 7A to 7L illustrate various stages of an example of a method for manufacturing an electronic device according to some embodiments of the present disclosure.

Referring to FIG. 7A, the electronic component 30 may be provided. The electronic component 30 may be embedded within the encapsulant 21 and encapsulant 22. A conductive material 71 may be formed under the lower surface of the encapsulant 21. A conductive material 72 may be formed over the upper surface of the encapsulant 22.

Referring to FIG. 7B, the conductive material 71 may be patterned to expose the lower surface of the encapsulant 21. The conductive material 72 may be patterned to expose the upper surface of the encapsulant 22.

Referring to FIG. 7C, the encapsulant 21 may be patterned by, for example, a laser drilling technique. The encapsulant 22 may be patterned by, for example, a laser drilling technique. The openings O1 may be formed to expose the terminals 33. The openings O1 may have different depths. The openings O2 may be formed to expose the terminals 34. The openings O2 may have different depths. The openings O3 may be formed to expose the conductive material 71. The openings O3 may be recessed from the conductive material 72.

Referring to FIG. 7D, a conductive material 73 may be formed over the conductive material 71. The conductive material 73 may be formed within the openings O1. The conductive material 73 may be formed by an electroless plating technique or other suitable techniques. A conductive material 74 may be formed over the conductive material 72. The conductive material 74 may be formed within the openings O2. The conductive material 74 may be formed within the openings O3. The conductive material 74 may be formed by an electroless plating technique or other suitable techniques.

Referring to FIG. 7E, a conductive material 75 may be formed under the conductive material 73. The conductive material 75 may be formed within the openings O1. The conductive material 75 may be formed by a plating technique or other suitable techniques. A conductive material 76 may be formed over the conductive material 74. The conductive material 76 may be formed within the openings O2. The conductive material 76 may be formed within the openings O3. The conductive material 76 may be formed by a plating technique or other suitable techniques.

Referring to FIG. 7F, the conductive material 71, conductive material 73, and conductive material 75 may patterned to form the conductive layer 13. The conductive material 72, conductive material 74, and conductive material 76 may patterned to form the conductive layer 62.

Referring to FIG. 7G, the substrate 11 may be formed under the conductive layer 13. The substrate 61 may be formed over the conductive layer 62. A conductive material 77 may be formed under the lower surface of the substrate 11. A conductive material 78 may be formed over the upper surface of the substrate 61.

Referring to FIG. 7H, the conductive material 77 and the substrate 11 may be patterned to form openings O4. The conductive material 78 and the substrate 61 may be patterned to form openings O5.

Referring to FIG. 7I, a conductive material 79 may be formed under the conductive material 77. The conductive material 79 may be formed within the openings O4. The conductive material 79 may be formed by an electroless plating technique or other suitable techniques. A conductive material 80 may be formed over the conductive material 78. The conductive material 80 may be formed within the openings O5. The conductive material 80 may be formed by an electroless plating technique or other suitable techniques.

Referring to FIG. 7J, a conductive material 81 may be formed under the conductive material 79. The conductive material 81 may be formed within the openings O4. The conductive material 82 may be formed by a plating technique or other suitable techniques. A conductive material 82 may be formed over the conductive material 80. The conductive material 82 may be formed within the openings O5. The conductive material 82 may be formed by a plating technique or other suitable techniques.

Referring to FIG. 7K, the conductive material 77, conductive material 79, and conductive material 81 may be patterned to define the conductive layer 12 and interconnections 14 and 16. The conductive material 78, conductive material 80, and conductive material 82 may be patterned to define the conductive layer 63 and interconnections 64 and 66.

Referring to FIG. 7L, the dielectric layer 15 may be formed under the conductive layer 12. The dielectric layer 65 may be formed over the conductive layer 63. As a result, an electronic device (e.g., the electronic device 1a) may be produced.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
an electronic component having a first group of terminals disposed on a lower surface of the electronic component and a second group of terminals disposed on an upper surface of the electronic component, wherein the first group of terminals comprise a first terminal and a second terminal disposed at different elevations; and
a first group of conductive vias electrically connected to the first group of terminals.

2. The electronic device of claim 1, further comprising:
a dielectric structure encapsulating the electronic component and the first group of conductive vias.

3. The electronic device of claim 2, wherein the dielectric structure comprises a bottom encapsulant and a top encapsulant stacked over the bottom encapsulant, and the electronic component is embedded within the bottom encapsulant and the top encapsulant.

4. The electronic device of claim 3, wherein the bottom encapsulant comprises a protruding portion in contact with the lower surface or a lateral surface extending between the upper surface and the lower surface of the electronic component.

5. The electronic device of claim 4, wherein the upper surface of the electronic component has a central region closer to the bottom encapsulant and a peripheral region far away from the bottom encapsulant.

6. The electronic device of claim 1, wherein the electronic component comprises a logic die and a carrier disposed between the first group of terminals and the logic die, and the logic die is configured to receive a power through the carrier.

7. The electronic device of claim 6, wherein the first group of terminals comprise a first terminal at a central region of the lower surface and a second terminal at a peripheral region of the lower surface, and the first group of conductive vias has a first via connected to the first terminal and a second via connected to the second terminal, and a length of the first via is less than a length of the second via.

8. The electronic device of claim 6, further comprising:
a second group of conductive vias connected to the second group of terminals, comprising a first via over a central region of the upper surface and a second via over a peripheral region of the upper surface, and a length of the first via is greater than a length of the second via.

9. The electronic device of claim 1, wherein an arrangement of the first group of conductive vias and an arrangement of the second group of conductive vias are non-symmetrical with respect to the electronic component.

10. An electronic device, comprising:
an electronic component having a lower surface and an upper surface; and
a first group of conductive vias disposed under the lower surface of the electronic component and electrically connected to the electronic component,
wherein the first group of conductive vias have different lengths.

11. The electronic device of claim 10, further comprising:
a first circuit structure supporting the first group of conductive vias, wherein the first group of conductive vias comprise a first via and a second via, a top of the first via is at a first elevation with respect to an upper surface of the first circuit structure, and a top of the second via is at a second elevation, with respect to the upper surface of the first circuit structure, higher than the first elevation.

12. The electronic device of claim 11, wherein a bottom of the first via is at a third elevation, and a bottom of the second via is at a fourth elevation substantially the same as the third elevation with respect to the upper surface of the first circuit structure.

13. The electronic device of claim 10, further comprising:
a second group of conductive vias disposed over the upper surface of the electronic component and electrically connected to the electronic component,
wherein the second group of conductive vias have different lengths.

14. The electronic device of claim 13, wherein a sum of a length of one of the first group of conductive vias and a length of one of the second group of conductive vias vertically overlapping the one of the first group of conductive vias is substantially identical to a sum of a length of another one of the first group of conductive vias and a length of another one of the second group of conductive vias directly over the another one of the first group of conductive vias.

15. The electronic device of claim 13, further comprising:
a second circuit structure disposed over the second group of conductive vias and connected to the second group of conductive vias, wherein the second group of conductive vias comprise a first via and a second via, a bottom of the first via is at a first elevation with respect to a lower surface of the second circuit structure, and a bottom of the second via is at a second elevation, with respect to the lower surface of the second circuit structure, higher than the first elevation.

16. The electronic device of claim 15, wherein the second via is closer to a side, extending between the upper surface and the lower surface, of the electronic component than to the first via.

17. The electronic device of claim 15, wherein a top of the first via is at a third elevation, and a top of the second via is at a fourth elevation substantially the same as the third elevation with respect to the lower surface of the second circuit structure.

18. An electronic device, comprising:
a lower circuit structure having a substantially flat surface;
an electronic component disposed over the substantially flat surface of the lower circuit structure, wherein the electronic component has a lower curved surface facing the substantially flat surface; and
first interconnections disposed between the substantially flat surface of the lower circuit structure and the lower curved surface of the electronic component.

19. The electronic device of claim 18, wherein the electronic component has a first side and a second side opposite to the first side, and a bottom of the first side is at an elevation different from that of a bottom of the second side with respect to the substantially flat surface of the lower circuit structure.

20. The electronic device of claim 18, wherein the electronic component has a first side and a second side connected to the first side, and a bottom of the first side is at an elevation different from that of a bottom of the second side with respect to the substantially flat surface of the lower circuit structure.
